(19) United States
(12) Patent Application Publication
(10) Pub. No.: US 2026/0189121 A1
(43) Pub. Date: Jul. 2, 2026

(54) SYSTEM AND METHOD FOR IDENTIFYING COMPROMISED COMPONENTS IN POWER CONVERSION DEVICES

(71) Applicant: FLUENCE ENERGY, LLC, Arlington, VA (US)

(72) Inventors: Brett Lance Galura, Vienna, VA (US); Thomas Jeffrey Winter, Decatur, GA (US)

(73) Assignee: FLUENCE ENERGY, LLC, Arlington, VA (US)

(21) Appl. No.: 18/868,302

(22) PCT Filed: Sep. 26, 2024
(86) PCT No.: PCT/US2024/048718

§ 371 Date: Nov. 22, 2024

Related U.S. Application Data
(60) Provisional application No. 63/541,126, filed on Sep. 28, 2023.

(51) Int. Cl. H02M 1/00; H02J 3/32; H02J 3/38; H02J 7/06; H02J 7/90; H02J 101/10; H02J 101/20; H02M 1/32; H02M 7/00

(52) U.S. Cl. CPC H02M 1/0009; H02J 3/32; H02J 3/381; H02J 7/06; H02J 7/933; H02M 1/327; H02M 7/003; H02J 2101/10; H02J 2101/20; H02J 2207/20

(57) ABSTRACT

An energy storage system a plurality of energy storage nodes. Each of the plurality of energy storage nodes include a plurality of battery storage elements. The energy storage system further includes a power conversion system (PCS); a control system coupled to the plurality of energy storage nodes and the PCS; and a plurality of sensors coupled to the control system to detect or monitor various system data. The system data includes PCS data from the PCS. The control system is configured to measure the PCS data including current and voltage on both input and output sides of the PCS. The control system is further configured to apply one or more PCS diagnostics models trained to determine behavioral characteristics of at least one component of the PCS based on the measured current and voltage and one or more behavioral patterns previously associated with abnormally behaving components of the PCS.

### CROSS-REFERENCE TO RELATED APPLICATIONS

This application claims priority to U.S. Provisional Patent Application No. 63/541,126, filed on Sep. 28, 2023, titled “System and Method for Identifying Compromised Components in Power Conversion Devices,” the entire disclosure of which is incorporated by reference herein.

### TECHNICAL FIELD

The present subject matter relates to energy storage systems that include a plurality of energy storage nodes and measuring a power conversion system (PCS) data including current and voltage on both input and output sides of the PCS. The present subject matter also encompasses applying one or more PCS diagnostics models trained to determine behavioral characteristics of at least one component of the PCS based on the measured current and voltage and one or more behavioral patterns previously associated with abnormally behaving components of the PCS.

### BACKGROUND

An energy storage system, such as a battery energy storage system (BESS), can be set up in a distributed manner to satisfy safety and economical concerns. The energy storage system often includes many energy storage nodes that each include an enclosure that houses many batteries inside. Typically, the energy storage system includes a control system that monitors the energy storage nodes and at least one power conversion system (PCS).

The energy storage system is made up of large, often expensive components designed to be as efficient as possible at performing the tasks of creating, storing, or provisioning energy. Downtime for these components can incur prohibitively high costs, and therefore maintenance and replacement of degraded components is urgent, and can come with rush fees, on top of the costs of parts and labor in repair and replacement. In particular, a PCS that includes an inverter can cause a disparate impact on downtime costs depending upon system robustness and redundancy. A single PCS going offline can render tens or hundreds of batteries, solar panels, or other energy storage and creation components ineffective. Consequently, an operator of the energy storage system wishes to operate their PCSs with as long a lifespan as possible, to reduce maintenance and replacement costs.

These costs are why scheduled maintenance is the preferred method of performing maintenance for the operator of the energy storage system. This method includes replacement of damaged and failed components, such as the PCS. Some components are serviced on a pre-set schedule that is time-based. Time-based service includes events, such as regularly scheduled inspections, for example a multi-point inspection of the PCS, with repair and replacement of atypical out-of-tolerance components and sub-components based on the results of one of the regularly scheduled inspections. Extending the life of the components of the PCS to fail beyond the next maintenance window would allow proper proactive repair to be performed in a cost-effective manner, and reduces or eliminates losses related to lack of available capacity. Time-based service is highly preferable to servicing components, in particular the PCS, on a break-fix basis.

The current state of the art of energy storage systems also involves break-fix repair. In break-fix repair, the equipment of the energy storage system is run until a component fails, and any actions or adaptations are made as a one-off repair activity, reactively rather than proactively. The failed component is repaired or replaced outside of the regularly scheduled inspections or maintenance, incurring rush costs, which severely limits any economy of scale in the maintenance process, particularly mobilization costs. Break-fix repair is more likely to include losses related to lack of available capacity. A non-working PCS generally results in lost system capacity, reducing customer satisfaction and potentially exposing system operators to liquidated damages. This one-off repair adds cost versus completing any necessary work during an already anticipated and scheduled maintenance window.

Current state of the art processes for energy storage systems do not proactively work to extend the lifetime of a PCS in operation. Currently, there is not a method or system in place to identify weak or damaged components in the PCS using a diagnostic process. In industry, there are no methods for identifying where weak or damaged components are present in the PCS. The PCS is run without knowledge regarding weak or damaged components within the PCS, and action is taken only upon failure of the PCS where the action includes replacement of the damaged and failed components. Techniques for making inferences around component state of the PCS are in a nascent stage of development.

Further, PCS manufacturers, who know and understand the components most deeply, have not made sufficient investments in PCS diagnostics techniques because they are not incentivized to do so. Generally, a PCS is covered by a limited warranty, one that does not cover financial losses related to lack of available capacity. The manufacturer of the PCS is only responsible for the cost of repairing or replacing the PCS itself. Further, the manufacturer is not in a position to determine the relative value of voluntarily reducing operational capacity versus the risk of catastrophic failure.

### SUMMARY

Hence, there is a need for systems directed to diagnostics of a power conversion system (PCS) in order to identify compromised components of the PCS. The PCS diagnostics technologies disclosed herein can identify weak or damaged components of the PCS by applying PCS diagnostics models. The PCS diagnostics technologies can determine programmatically what adjustments, such as modifications, changes, or updates in operating limits or operating profiles, can be implemented to extend the lifetime of weak or damaged components of the PCS. The PCS diagnostics technologies can adjust the operating limits or operating profiles such that improved component lifetime before failure is achieved in the PCS, either indefinitely or until scheduled maintenance can occur.

Additionally, the PCS diagnostics technologies can notify a service or maintenance team that weak components have been identified in the PCS, and that adaptive measures have been taken. The PCS diagnostics technologies can allow maintenance schedules to be updated appropriately, accommodating the changes needed to maximize energy storage system availability based on the gained knowledge. By adjusting operating conditions, such as operating limits and operating profiles, the lifetime of weak and damaged components of the PCS can be extended. The PCS therefore lasts longer prior to failure, reducing component costs related to the repair itself. The work performed by a service or maintenance team to address the weak or damaged components can be included in normal scheduled maintenance, reducing mobilization costs.

In a first example, an energy storage system 101 includes a plurality of energy storage nodes 105A-N. Each of the plurality of energy storage nodes 105A-N include a plurality of battery storage elements 106A-N. The energy storage system 101 further includes a power conversion system (PCS) 104 including a plurality of components 152, 153, 205, 210, 215; and a control system 115 coupled to the plurality of energy storage nodes 105A-N and the PCS 104. The energy storage system 101 further includes a plurality of sensors 164A-N, 168A-N, 315A-N, 370A-N, 375A-N coupled to the control system 115 to detect or monitor various system data 380A-N. The system data 380A-N includes PCS data 157A-N from the PCS 104. The control system 115 is configured to measure the PCS data 157A-N including an input current 122A and an input voltage 123A on an input side 190 of the PCS 104 and an output current 122B and an output voltage 123B on an output side 191 of the PCS 104. The control system 115 is further configured to apply one or more PCS diagnostics models 395A-N trained to determine behavioral characteristics 390A-N of at least one component 152, 153, 205, 210, 215 of the PCS 104 based on the measured input current 122A, the input voltage 123A, the output current 122B, and the output voltage 123B and one or more behavioral patterns 399A-N previously associated with abnormally behaving components of the PCS 104.

In a second example, a non-transitory computer-readable medium, 313, 353 includes PCS diagnostics programming 330A-B. Execution of the PCS diagnostics programming 330A-B by one or more processors 312, 352 configures one or more controllers 110, 115, 170-173 to measure a power conversion system (PCS) data 157A-N including an input current 122A and an input voltage 123A on an input side 190 of a PCS 104 and an output current 122B and an output voltage 123B on an output side 191 of the PCS 104. Execution of the PCS diagnostics programming 330A-B by one or more processors 312, 352 configures one or more controllers 110, 115, 170-173 to apply one or more PCS diagnostics models 395A-N trained to determine behavioral characteristics 390A-N of at least one component 152, 153, 205, 210, 215 of the PCS 104 based on the measured input current 122A, the input voltage 123A, the output current 122B, and the output voltage 123B and one or more behavioral patterns 399A-N previously associated with abnormally behaving components of the PCS 104.

In a third example, a method 600 includes measuring a power conversion system (PCS) data 157A-N including an input current 122A and an input voltage 123A on an input side 190 of a PCS 104 and an output current 122B and an output voltage 123B on an output side 191 of the PCS 104. The method 600 further includes applying one or more PCS diagnostics models 395A-N trained to determine behavioral characteristics 390A-N of at least one component 152, 153, 205, 210, 215 of the PCS 104 based on the measured input current 122A, the input voltage 123A, the output current 122B, and the output voltage 123B and one or more behavioral patterns 399A-N previously associated with abnormally behaving components of the PCS 104. The method 600 further includes responsive to the determined behavioral characteristics 390A-N, performing at least one of adjusting an operation of the PCS 104, servicing the at least one component 152, 153, 205, 210, 215 of the PCS 104, or selecting one or more operating conditions 391A-N of the at least one component 152, 153, 205, 210, 215 of the PCS 104.

Additional objects, advantages and novel features of the examples will be set forth in part in the description which follows, and in part will become apparent to those skilled in the art upon examination of the following and the accompanying drawings or may be learned by production or operation of the examples. The objects and advantages of the present subject matter may be realized and attained by means of the methodologies, instrumentalities and combinations particularly pointed out in the appended claims.

### BRIEF DESCRIPTION OF THE DRAWINGS

The drawing figures depict one or more implementations, by way of example only, not by way of limitations. In the figures, like reference numerals refer to the same or similar elements.

FIG. 1A depicts a system that includes an energy storage system, energy system, and an electrical application.

FIG. 1B depicts a battery array, an array controller, and core controllers of an example architecture of a control system of FIG. 1A.

FIG. 1C depicts the array controller, the core controllers, node controllers, and enclosure controllers in the example architecture of the control system of FIGS. 1A-B.

FIG. 1D depicts a power conversion system of a battery core of FIG. 1A-C.

FIG. 2A illustrates a first energy storage node of a plurality of energy storage nodes of the energy storage system of FIGS. 1A-C coupled to the electrical application.

FIG. 2B illustrates a first energy storage node that includes a plurality of battery cubes and a plurality of power conversion systems coupled to a DC link (DC bus).

FIG. 3A is a high-level functional block diagram of the energy storage system of FIG. 1A that depicts components of the control system and control subsystem for PCS diagnostics of the energy storage system.

FIG. 3B is another high-level functional block diagram of the energy storage system of FIGS. 1B-C that depicts components of the control system with various controllers for PCS diagnostics of the energy storage system.

FIG. 3C is a block diagram of the control system depicting various types of battery conditions.

FIG. 4A is a PCS diagnostics protocol for the energy storage system of FIG. 1A that is implemented by the control system, the control subsystem, and the plurality of energy storage nodes.

FIG. 4B is the PCS diagnostics protocol for the energy storage system of FIGS. 1B-C that is implemented by the various controllers of the control system and the plurality of energy storage nodes.

FIG. 5 is a cutaway view of the first energy storage node of the plurality of energy storage nodes and shows details of a plurality of battery storage elements.

FIG. 6 is a flowchart of a method that can be implemented for PCS diagnostics of the energy storage system.

Parts Listing

| | |
|---|---|
| 100 | System |
| 101 | Energy Storage System |
| 102 | Energy System |
| 103 | Electrical Application |
| 104, 104A-N | Power Conversion Systems |
| 105A-N | Energy Storage Nodes |
| 106, 106A-N | Battery Storage Elements |
| 107, 107A-N | Power Conversion Subsystems |
| 108 | Transformer |
| 109 | Energy Source |
| 110 | Control Subsystem |
| 111A-N | Battery Data |
| 112 | Required Power Flow |
| 115 | Control System |
| 116A-O | Battery Conditions |
| 116A, 316A-N | State of Charge (SOC) |
| 120 | Physical Space |
| 122A-B | Current |
| 123A-B | Voltage |
| 125 | Power Bus |
| 150 | Battery Array |
| 151A-N | Battery Cores |
| 152 | Power Conversion Unit |
| 153 | HVAC Equipment |
| 154 | Fan |
| 155 | Condenser |
| 156 | Heater |
| 157A-N | PCS Data |
| 160 | PCS Controller |
| 161 | Network Communication Interface |
| 162 | Processor |
| 163 | Memory |
| 164A-N | Environmental Sensors |
| 165A-N | Environmental Condition Data |
| 168A-N | PCS Sensors |
| 170 | Array Controller |
| 171, 171A-N | Node Controllers |
| 172, 172A-N | Core Controllers |
| 173, 173A-N | Enclosure Controllers |
| 174 | Market Dispatch Unit Controller |
| 183, 183A-N | Power Commands |
| 190 | Input Side |
| 191 | Output Side |
| 205 | Power Inverter |
| 210 | Rectifier |
| 215 | DC-DC Converter |
| 225 | DC Link (DC Bus) |
| 230, 230A-N | Battery Cubes |
| 250 | DC Link Voltage |
| 305, 305A-N | Network |
| 311, 351 | Network Communication Interface |
| 312, 352 | Processor |
| 313, 353 | Memory |
| 315A-N | Sensors |
| 330, 330A-B | PCS Diagnostics Programming |
| 365A-N | Environmental Condition Data |
| 370A-N | Environmental Sensors |
| 375A-N | Battery Sensors |
| 380A-N | System Data |
| 390A-N | Behavioral Characteristics |
| 391A-N | Operating Conditions |
| 392 | Normal Operation |
| 393 | Operational Bias |
| 394 | Maintenance Operation |
| 395A-N | PCS Diagnostics Models |
| 398A-N | Time Periods |
| 399A-N | Behavioral Patterns |
| 400 | PCS Diagnostics Protocol |
| 500 | Enclosure |
| 600 | Method |

### DETAILED DESCRIPTION

In the following detailed description, numerous specific details are set forth by way of examples in order to provide a thorough understanding of the relevant teachings. However, it should be apparent to those skilled in the art that the present teachings may be practiced without such details. In other instances, well known methods, procedures, components, and/or circuitry have been described at a relatively high-level, without detail, in order to avoid unnecessarily obscuring aspects of the present teachings.

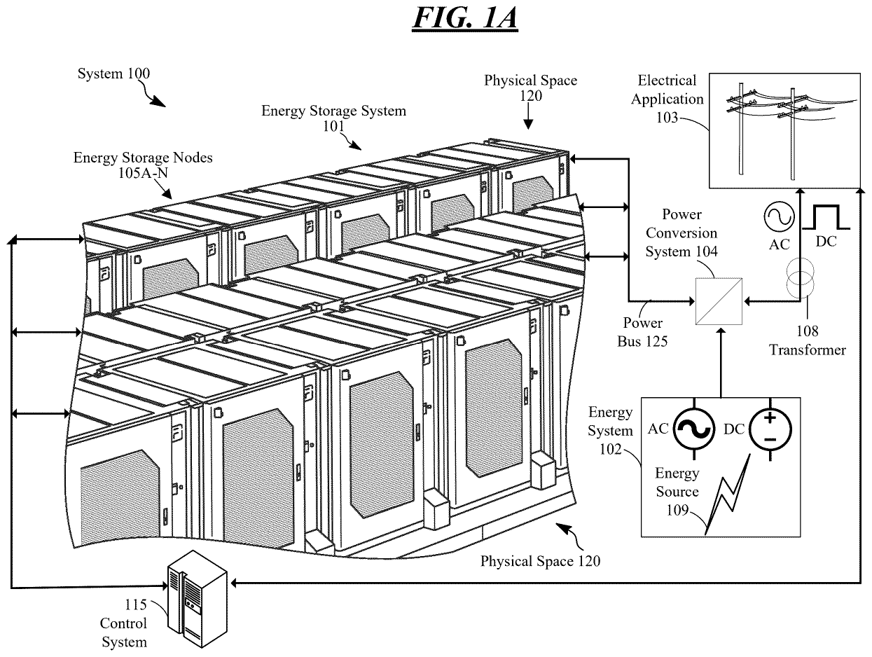

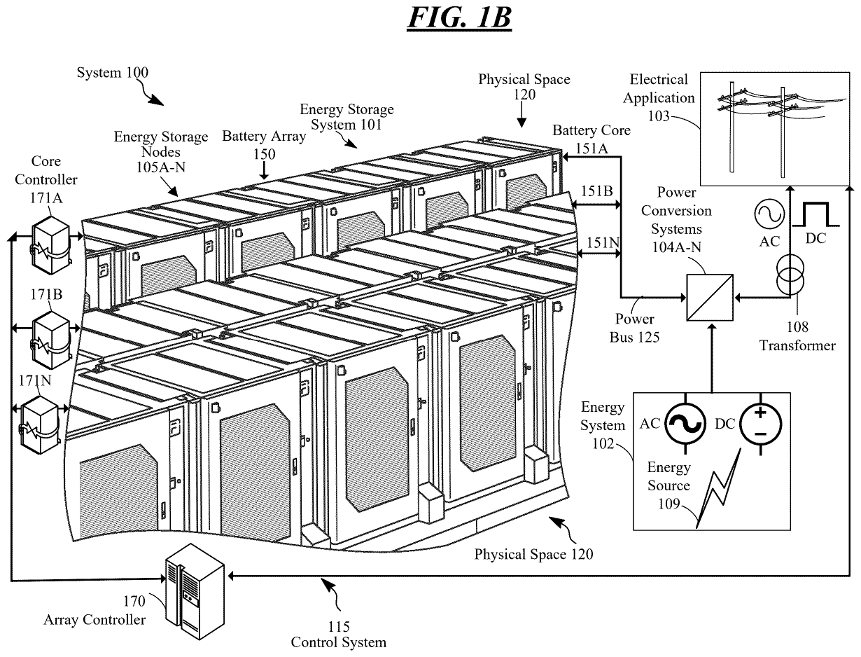

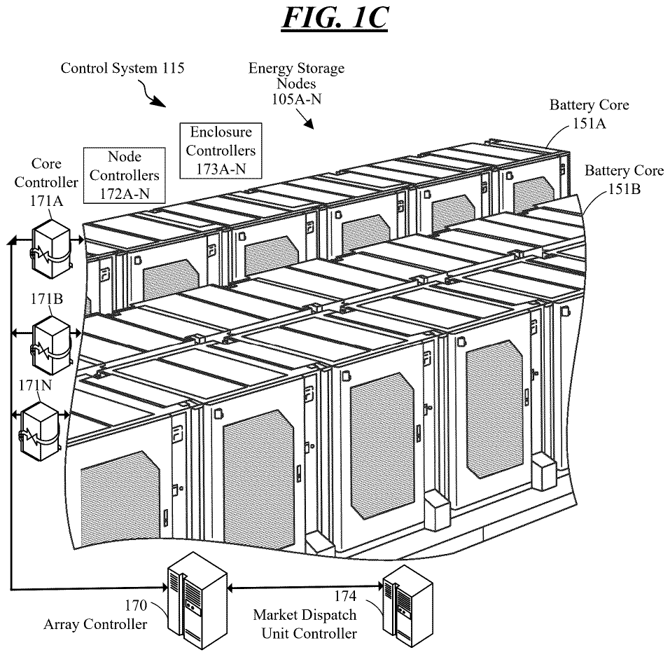

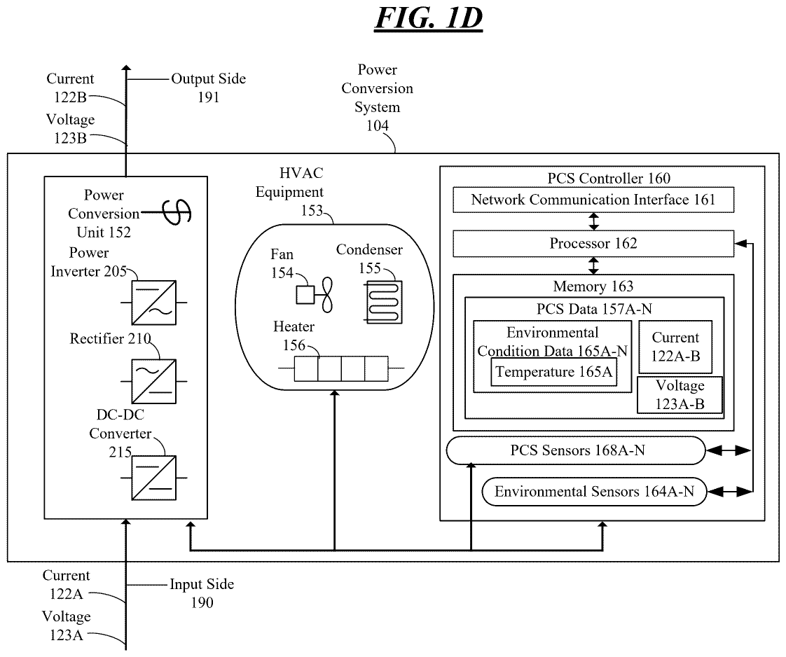

Unless otherwise indicated, any embodiment can be combined with any other embodiment. In particular, FIGS. 1A-6 and the associated text are all combinable with each other.

The term “coupled” as used herein refers to any logical, physical, electrical, or optical connection, link or the like by which electricity, power, signals, or light produced or supplied by one system element are imparted to another coupled element. Unless described otherwise, coupled elements or devices are not necessarily directly connected to one another and may be separated by intermediate components, elements, or communication media that may modify, manipulate or carry the electricity, power, signals, or light.

The orientations of the system 100, energy storage system 101, energy storage nodes 105A-N, associated components, and/or any complete devices, incorporating battery storage elements 106A-N, such as batteries, such as shown in any of the drawings, are given by way of example only, for illustration and discussion purposes. In operation for a particular energy storage application, an energy storage node 105A-N may be oriented in any other direction suitable to the particular application of the energy storage system 101, for example upright, sideways, or any other orientation. Also, to the extent used herein, any directional term, such as left, right, front, rear, back, end, up, down, upper, lower, top, bottom, and side, are used by way of example only, and are not limiting as to direction or orientation of any energy storage system 101 or energy storage nodes 105A-N; or component of an energy storage system 101 or energy storage nodes 105A-N constructed as otherwise described herein.

Unless otherwise indicated, any coupled electrical components can be linked in series or in parallel. In the case of energy storage nodes 105A-N or battery storage elements 106A-N, the components may be linked in series, in parallel, or a combination thereof depending upon a state of a switch or a submodule.

Reference now is made in detail to the examples illustrated in the accompanying drawings and discussed below.

FIG. 1A depicts a system 100 that includes an energy storage system 101, energy system 102, and an electrical application 103. FIG. 1B depicts a battery array 150, an array controller 170, and core controllers 171A-N of an example architecture of a control system 115 of FIG. 1A.

Referring to both FIGS. 1A-B, for example, the energy storage system 101 can be a battery energy storage system (BESS). The energy storage system 101 is coupled to the energy system 102 and the electrical application 103. Energy storage system 101 can include one or more power conversion systems (PCSs) 104A-N, a plurality of energy storage nodes 105A-N, an optional transformer 108, and a control system 115. Components of the energy storage system 101 can be located at a physical space 120 that is outdoors or indoors, for example, inside of a building, a container, or other structure.

Energy storage system 101 comprises a battery array 150 including a plurality of battery cores 151A-N including a first set of battery cores 151A-C and a second set of battery cores 151D-F, for example. Each of the battery cores 151A-N include at least one power conversion system 104A-N. In an example, there can be one PCS 104 and one transformer 108 per battery core 151A-N (at the battery core level).

As described in further detail below, energy storage system 101 can include a control system 115 coupled to the energy storage nodes 105A-N and the PCS 104. The control system 115 can include one or more controllers 170-174, such as an array controller 170, core controllers 171A-N, node controllers 172A-N, enclosure controllers 173A-N, and a market dispatch unit controller 174. The control system 115 is configured to control the battery cores 151A-N to dispatch a required power flow 112.

Power conversion systems 104A-N are coupled to the plurality of energy storage nodes 105A-N. The power conversion systems 104A-N are coupled to the energy system 102 and the electrical application 103 to provide a required power flow 112 to the electrical application 103 by discharging the plurality of energy storage nodes 105A-N or the required power flow 112 from the energy system 102 for charging the plurality of energy storage nodes 105A-N. The power conversion systems 104A-N can be coupled to an optional transformer 108. The optional transformer 108 can step up or step down the required power flow 112 to and from the electrical application 103, such as an AC voltage.

Energy system 102 can include any suitable system for producing electrical energy from an energy source 109. Energy system 102 can be a renewable energy system in which the energy source 109 can be replenished. Such a renewable energy source 109 can include solar power, wind power, geothermal power, biomass, and hydroelectric power. For example, the renewable energy system 102 can be implemented as an array of photovoltaic modules. The photovoltaic (PV) modules can include crystalline silicon, amorphous silicon, copper indium gallium selenide (CIGS) thin film, cadmium telluride (CdTe) thin film, and concentrating photovoltaic which uses lenses and curved mirrors to focus sunlight onto small, but highly efficient, multi-junction solar cells. In another example, the energy system 102 can include wind turbines or gas turbines. In some examples, the energy system 102 can be a non-renewable energy system in which the energy source 109 includes a non-renewable energy source, such as a fossil fuel.

Electrical application 103 can include an electrical grid, such as a power grid, or a smaller local load, such as a backup power system, for a facility such as a hospital, manufacturing site, residential home, or other suitable facility. The electrical application 103 may deliver AC or DC power for on-grid or off-grid applications, including commercial, industrial, or residential applications. The electrical application 103 may deliver power to buildings, electric vehicle charging stations, etc., including a variety of electrical loads that consume AC or DC electric power. The electrical application 103 can be a front-of-the-meter system that is owned or operated by a utility company or a behind-the-meter system that directly supplies buildings and homes with electricity.

Energy source 109 can be a renewable energy source, such as solar power and wind power, which can be intermittent and less reliable compared to fossil fuels. To improve resiliency, energy storage system 101 can store energy from the energy system 102 when the production from the energy source 109 is high. Later on, the energy storage system 101 can dispatch the energy to the electrical application 103 when demand is high or production from the energy source 109 is not keeping up with demand. Moreover, events may occur when a connected load or an operating demand load of the electrical application 103 is excessive or there is electrical grid instability, such as during extreme weather. By storing energy from the energy source 109 and then dispatching the energy during such events, the energy storage system 101 can continue to dispatch a required power flow 112 of the electrical application 103.

Energy storage nodes 105A-N include battery storage elements 106A-N. The battery storage elements 106A-N can be: (1) a single battery cell; (2) a cell grouping, including several battery cells in parallel configuration; (3) a battery submodule or module, including several battery cells in parallel and serial configuration; (4) a battery string, including several battery modules in series; (5) a battery bank, including several battery strings in parallel; (6) other known energy storage elements; and/or (7) a combination thereof. For example, the battery storage elements 106A-N can include a plurality of batteries of any existing or future reusable battery technology, including, but not limited to lithium ion, flow batteries, or mechanical storage, such as flywheel energy storage, compressed air energy storage, pumped-storage hydroelectricity, gravitational potential energy, or a hydraulic accumulator.

FIG. 1C depicts the array controller 170, the core controllers 171A-N, node controllers 172A-N, and enclosure controllers 173A-N in the example architecture of the control system 115 of FIGS. 1A-B. In the example, each of the energy storage nodes 105A-N can be a collection of one or more battery cubes 230A-N and every battery cube 230A-N includes an enclosure controller 173. A node controller 172 is the lowest controllable element of a battery core 151 for an energy storage node 105A-N and controls an individual energy storage node 105. A core controller 171 is the next higher level, which controls a subset of the energy storage nodes 105A-N, where each core represents branches of components of the energy storage system 101. The core controller 171 is a logical controller and can represent a transformer 108 that stands between the PCS 104 and the rest of the plant. Core controller 171 is an aggregator of different node controllers 172A-N and propagates power commands 183A-N from the array controller 170 to the node controllers 172A-N.

Array controller 170 is higher than the core controllers 171A-N and controls the overall energy storage system 101. The software for the array controller level can be installed at a customer installation site and can execute at the installation site, off-site, or a combination thereof. The array controller 170 can be a local decentralized service that runs onsite in real time.

A market dispatch unit controller 174 is a network wide controller and sits on top of the array controller 170 and looks at specific market requirements. The market dispatch unit controller 174 sets dispatch setpoints in terms of active and reactive power to the array controller 170 which deals with the energy storage system 101.

A battery core 151 can have multiple node controllers 172A-N depending on the number of energy storage nodes 105A-N and bus architecture of the battery core 151. In an example, if the PCS 104 is used as a single bus element, then there may be only one node controller 172 behind a core controller 171 for a single energy storage node 105A and only one PCS 104 per energy storage node 105A. But if the PCS 104 is used with multiple DC connections in a split bus architecture where a plurality of energy storage nodes 105A-D (e.g., four) are connected to the bus, there can be a plurality of energy storage nodes 105A-D on the bus and only one PCS 104 for all of the plurality of energy storage nodes 105A-D.

FIG. 1D depicts a power conversion system 104 of a battery core 151 of FIGS. 1A-C. As shown, the power conversion system 104 can include a power conversion unit 152, which can include a power inverter 205, rectifier 210, DC-DC converter 215, etc., or a combination thereof. The power conversion unit 152 can be an insulated-gate bipolar transistor (IGBT) module that is part of the PCS 104. The IGBT module can include an array of transistors (e.g., switching semiconductors), capacitors (e.g., filter capacitors), and any other power electronic devices to convert power. On one side of the power conversion unit 152 can be AC current and the other side DC current. The IGBT module is standard, but a variety of architectures can be used.

Power conversion system 104 further includes a heating, ventilation, and air conditioning (HVAC) equipment 153 to maintain the temperature of equipment of the PCS 104, such as the power conversion unit 152, within operating limits. The HVAC equipment 153 can include an air conditioner, such as a fan 154 and a condenser 155 to cool down the power conversion unit 152 (e.g., IGBT module). The HVAC equipment 153 can further include a heater 156.

The power conversion system 104 further includes a PCS controller 160 and environmental sensors 164A-N to protect the equipment of the PCS 104. Environmental sensors 164A-N, 370A-N can include water ingress sensors to detect water inside an enclosure of the PCS 104 or an enclosure 500 of a battery cube 230, gas sensors, particulate sensors, air sensors, or air pressure sensors. Infrared sensors can be used to detect temperature 165A, 375A such as heat inside enclosures of the PCS 104 or battery cube 230.

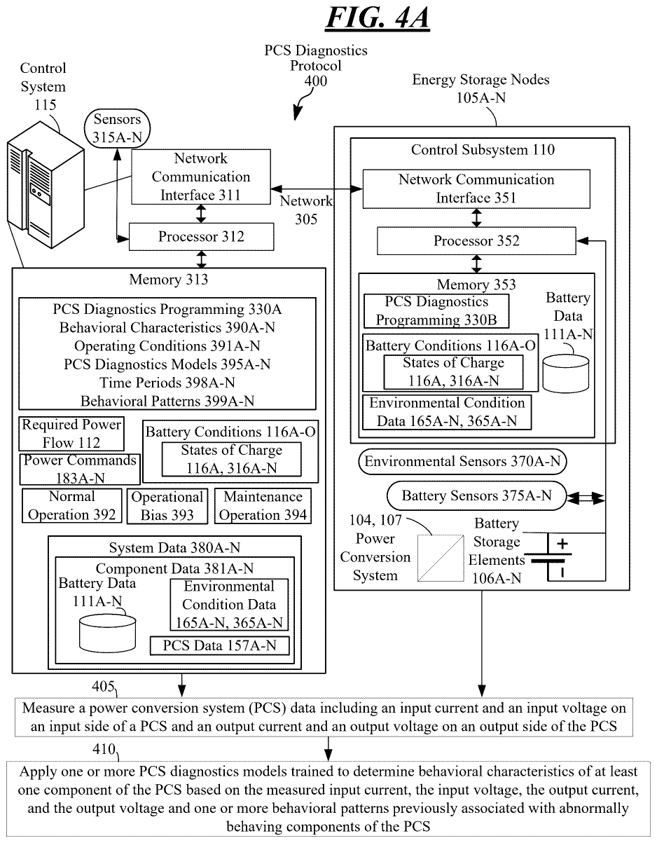

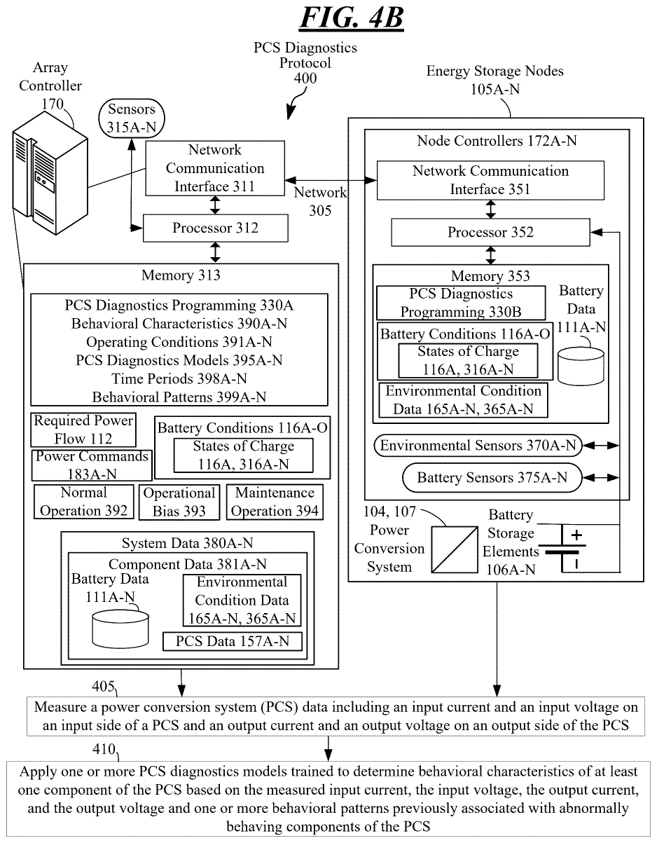

As shown, the PCS controller 160 includes a network communication interface 161, a processor 162, and a memory 163. The PCS 104 further includes PCS sensors 168A-N to measure a current 122A-B (e.g., a current magnitude) and a voltage 123A-B (e.g., DC link voltage). The environmental sensors 164A-N are coupled to the processor 163 and can collect environmental condition data 165A-N, for example, by measuring temperature 165A and humidity 165B inside of an enclosure of the PCS 104. The memory 163 can store the PCS data 157A-N, including the environmental condition data 165A-N collected by the environmental sensors 164A-N and the current 122 and the voltage 123 collected by PCS sensors 168A-N. The PCS data 157A-N, including the environmental condition data 165A-N, such as temperature 165A, current 122, and voltage 123 are monitored during the PCS diagnostics protocol 400 (see FIGS. 4A-B) and acted upon.

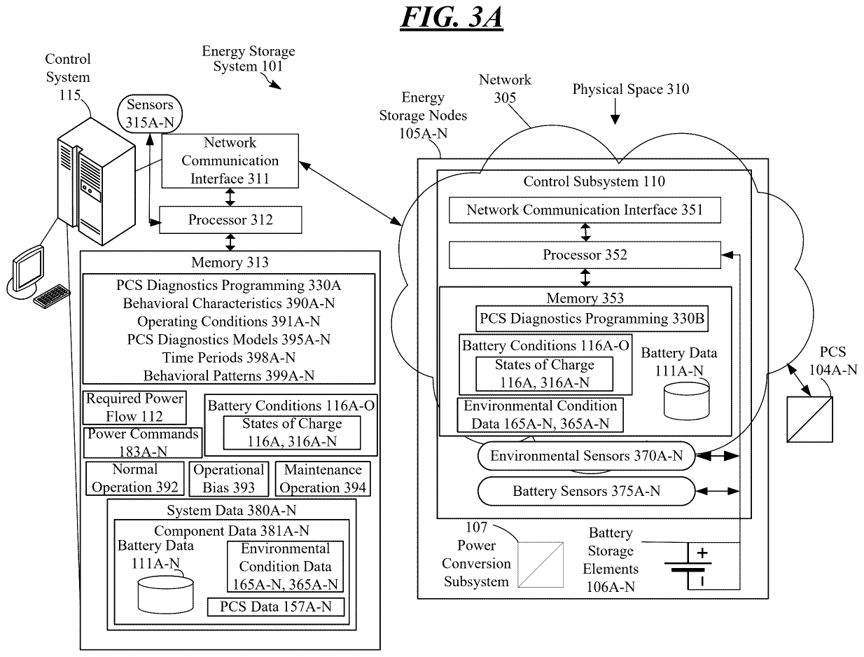

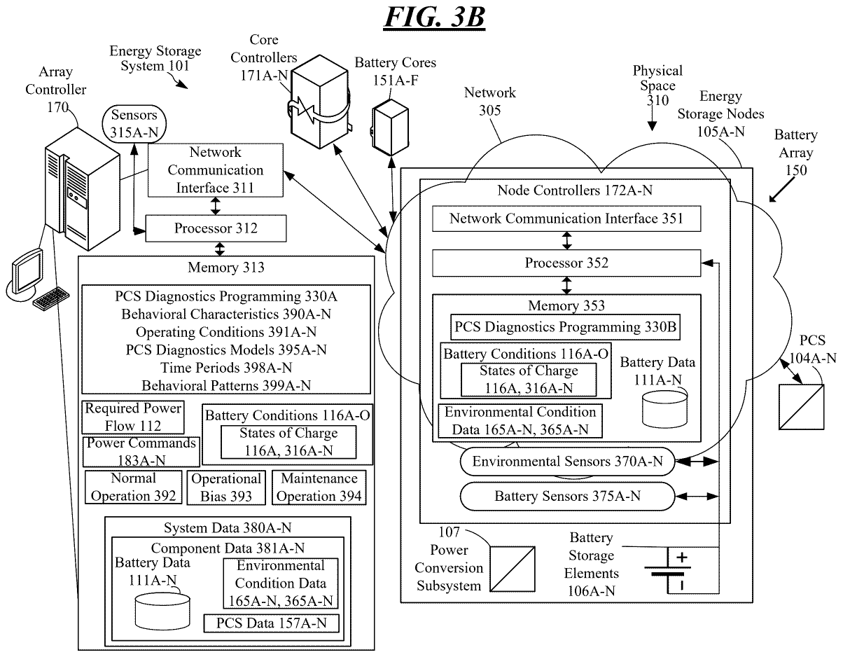

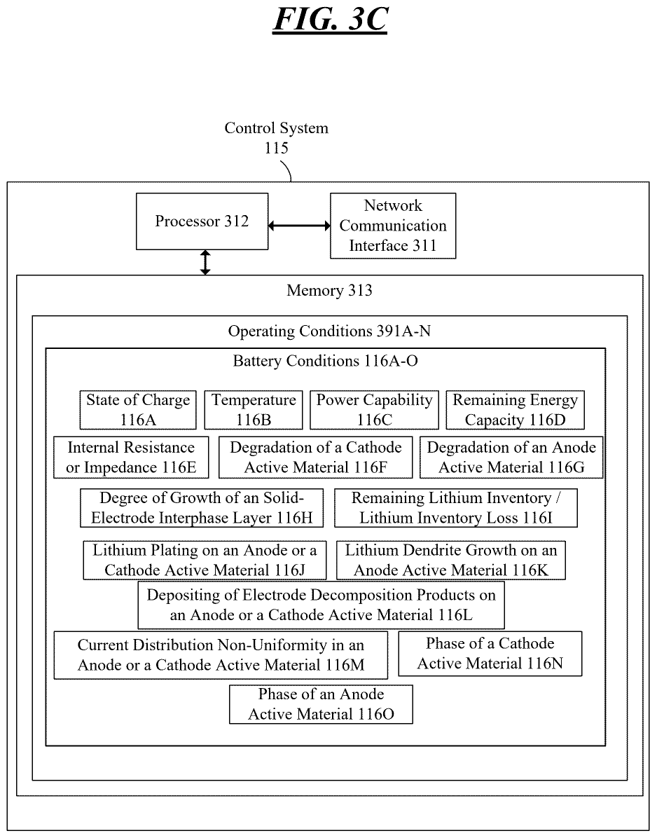

Control system 115 implements a PCS diagnostics protocol 400 (see FIGS. 4A-B) which can be implemented in PCS diagnostics programming 330A-B (see FIGS. 3A-B). The PCS diagnostics protocol 400 can use current and voltage measurements 122A-B, 123A-B on both the input side 190 (e.g., DC side) and the output side 191 (e.g., AC side) of the power conversion system 1 (e.g., power inverter 205). These current and voltage measurements 122A-B, 123A-B can be run through one or more PCS diagnostics models 395A-N which have been trained to associate certain behavioral patterns 399A-N in the current and voltage measurements 122A-B, 123A-B with weakened or failing components 152, 153, 205, 210, 215 in the power conversion system 104. The PCS diagnostics protocol 400 can adjust operating conditions 391A-N, such as operating limits or operating profiles responsive to determined behavioral characteristics 390A-N, to extend the lifetime of such components 152, 153, 205, 210, 215. For example, the operating conditions 391A-N can reduce power limits, limit operation to certain voltage ranges, reduce the rate of change of power output, or change active/reactive power ratios.

PCS diagnostics models 395A-N can include one or more mathematical classifications or representations, such as equations, that describe how parameters, such as the PCS data 157A-N, relates to each other over time, space, and other system data 380-N to gain insights into at least one component 152, 153, 205, 210, 215 of the PCS 104. The PCS diagnostics models 395A-N can include values and relations between various parameters, such as the system data 380A-N, including the PCS data 157A-N, involved in forming an expression to describe the behavior, such as a weakness, damage, or a changed condition, under assumed boundary conditions of the sat least one component 152, 153, 205, 210, 215 of the PCS 104.

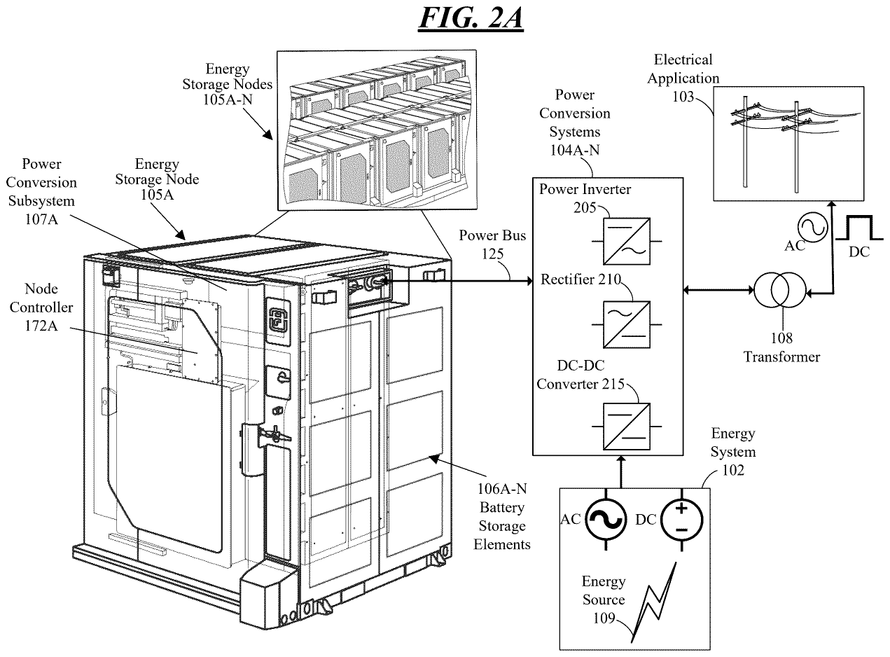

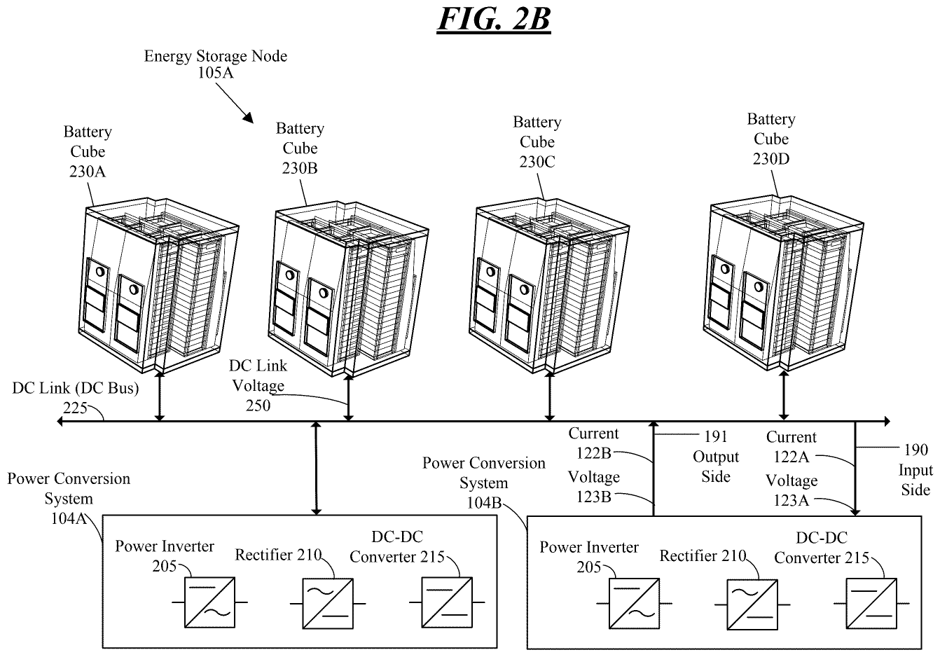

FIG. 2A illustrates a first energy storage node 105A of the plurality of energy storage nodes 105A-N of FIGS. 1A-C coupled to the electrical application 103. The first energy storage node 105A can include a single battery cube 230A (as in the case of FIG. 2A) or a plurality of battery cubes 230A-D (as in the case of FIG. 2B). Energy storage nodes 105A-N can include a battery storage element 106, a power conversion system 104 (or a power conversion subsystem 107), and a node controller 172 (or a control subsystem 110) to receive battery data 111A-N from the battery storage element 106, PCS data 157A-N from the power conversion system 104 (or the power conversion subsystem 107), or a combination thereof.

Power conversion system 104 (or the power conversion subsystem 107) can include a power inverter 205, a rectifier 210, a DC-DC converter 215, other power conversion elements, or a combination thereof. Power inverter 205 can be configured to convert a DC source, such as from the battery storage elements 106A-N, into an AC waveform. Rectifier 210 can be configured to convert an AC source, such as from the energy system 102 or electrical application 103, into DC for the battery storage elements 106A-N. DC-DC converter 215 can be configured to convert a DC source, such as from the battery storage elements 106A-N, into a different DC source characteristic.

If the energy source 109 is wind power, then the power conversion system 104 can convert the AC electricity produced into DC power for storage in the plurality of energy storage nodes 105A-N via the rectifier 210. If the energy source 109 is solar power, then the power conversion system 104 can convert the DC electricity into a different voltage level via the DC-DC converter 215. The power inverter 205 can convert the required power flow 112 from the energy storage system 101 from DC power into AC power during dispatch to the electrical application 103. For example, the power inverter 205 can be configured to convert power on a power bus 125 (e.g., AC bus, DC bus, or both) for use by the electrical application 103. For example, the power inverter 205 converts DC power stored in the energy storage nodes 105A-N into AC power for consumption by electrical loads of the electrical application 103.

Power conversion subsystem 107 includes similar hardware and software as the more centralized power conversion system 104. Power conversion subsystem 107 can be distributed more locally to each of energy storage nodes 105A-N. The node controller 172 and the control subsystem 110 can be configured for local computation, processing, and control of the battery storage elements 106A-N and the power conversion subsystem 107. The control system 115 and the array controller 170 can be configured for more centralized computation, processing, and controls of the overall energy storage system 101, energy system 102, electrical application 103, and power conversion system 104. The various controllers 170-173 of the control system 115, including the array controller 170, core controllers 171A-N, node controllers 172A-N, and enclosure controllers 173A-N can include a computing device, single board computer, an application-specific integrated circuit (ASIC), microcontroller, digital signal processor (DSP), field-programmable gate array (FPGA), or a combination thereof.

FIG. 2B illustrates a first energy storage node 105A that includes a plurality of battery cubes 230A-N and a plurality of power conversion systems 104A-N coupled to a DC link (DC bus) 225. As shown, the first energy storage node 105A includes four battery cubes 230A-D and two power conversion systems 104A-B coupled to the DC link (DC bus) 225 in the example. The first energy storage node 105A can be arranged so the battery cubes 230A-B are connected to a DC bus 225A with the PCS 104A in a split bus architecture. Battery cubes 230C-D can be connected to a DC bus 225B with the PCS 104B also in a split bus architecture. Battery sensors 375A-N can measure a DC link voltage 250 of the battery cube 230B on the DC bus 225A. PCS sensors 168A-N can measure a DC link voltage 123 of the PCS 104B on the DC bus 225B.

As depicted in FIG. 2B, the control system 115 can measure the PCS data 157A-N including an input current 122A and an input voltage 123A on an input side 190 of the PCS 104B and an output current 122B and an output voltage 123B on an output side 191 of the PCS 104B.

FIG. 3A is a high-level functional block diagram of the energy storage system 101 of FIG. 1A that depicts components of the control system 115 and the control subsystem 110 for PCS diagnostics of the energy storage system 101. FIG. 3B is another high-level functional block diagram of the energy storage system of FIGS. 1B-C that depicts components of the control system 115 with various controllers 170-173 for PCS diagnostics of the energy storage system 101.

Referring to FIGS. 3A-B, as shown, each of the plurality of energy storage nodes 105A-N can include a battery storage element 106A-N; a power conversion subsystem 107; and a control subsystem 110 (FIG. 3A) or a node controller 172 (FIG. 3B) to receive battery data 111A-N from the battery storage element 106A-N, PCS data 157A-N from the power conversion subsystem 107, or a combination thereof. The control system 115 can be coupled to the energy storage nodes 105A-N and the PCS 104 and configured to receive battery data 111A-N from the battery storage element 106, PCS data 157A-N from the power conversion system 104 (or power conversion subsystem 107), or a combination thereof.

The control subsystem 110; control system 115, including the array controller 170, core controllers 171A-N, node controllers 172A-N, and enclosure controllers 173A-N; energy storage nodes 105A-N; electrical application 103; and other components of the system 100 can be in communication over a network 305 or one or more networks 305A-N. The networks 305A-N can be a local area network 305A, wide area network 305B, or a combination thereof. For example, the control system 115 can be coupled via a local area network 305A to the energy storage nodes 105A-N and the electrical application 103. Alternative or additionally, the control system 115 can be coupled via a wide area network 305B to the energy storage nodes 105A-N and electrical application 103. Or the control system 115 can be coupled via a combination of networks 305A-N, such as via a local area network 305A to components of the energy storage system 101, including the energy storage nodes 105A-N, and coupled via a wide area network 305B to the electrical application 103.

An example energy storage system 101 includes a plurality of energy storage nodes 105A-N. Each of the plurality of energy storage nodes 105A-N include a plurality of battery storage elements 106A-N. The energy storage system 101 further includes a power conversion system (PCS) 104 including a plurality of components 152, 153, 205, 210, 215. The energy storage system 101 further includes a control system 115 coupled to the plurality of energy storage nodes 105A-N and the PCS 104. The energy storage system 101 further includes a plurality of sensors 164A-N, 168A-N, 315A-N, 370A-N, 375A-N coupled to the control system 115 to detect or monitor various system data 380A-N. The system data 380A-N includes PCS data 157A-N from the PCS 104.

The functionality of the control system 115 described herein, including the PCS diagnostics protocol 400 and PCS diagnostics programming 330A-B, can be divided across one or more computing devices that are coupled via a network 305. The control system 115 is configured to measure the PCS data 157A-N including an input current 122A and an input voltage 123A on an input side 190 of the PCS 104 and an output current 122B and an output voltage 123B on an output side 191 of the PCS 104. The control system 115 is further configured to apply one or more PCS diagnostics models 395A-N trained to determine behavioral characteristics 390A-N of at least one component 152, 153, 205, 210, 215 of the PCS 104 based on the measured input current 122A, the input voltage 123A, the output current 122B, and the output voltage 123B and one or more behavioral patterns 399A-N previously associated with abnormally behaving components of the PCS 104.

The PCS diagnostics programming 330A-B can apply PCS diagnostics models 395A-N that include signal processing to determine the behavioral characteristics 390A-N, such as tendencies, trends, relationships, or correlations of when the PCS 104 is run in certain ways whether a potential weakness or damage to components 152, 153, 205, 210, 215 of the PCS 104 appear to be present. The signal processing builds up a history or library, such as a fingerprint, of what the weakness or damage in the components 152, 153, 205, 210, 215 of the PCS 104 looks like over a variety of operating conditions 391A-N of the energy storage nodes 105A-N and the PCS 104. The fingerprint can be created based on the signal processing so that an operational bias 393 can be applied to extend a lifetime of the weakened or damaged components 152, 153, 205, 210, 215 of the PCS 104 by adjusting operation to take advantage of that information.

PCS diagnostics models 395A-N can determine how close to specifications or expected values the at least one component 152, 153, 205, 210, 215 is behaving via the behavioral characteristics 390A-N. The determined behavioral characteristics 390A-N can indicate the at least one component 152, 153, 205, 210, 215 may not be weakened or failing but trending away from a specification or value that is expected. The determined behavioral characteristics 390A-N can also indicate the at least one component 152, 153, 205, 210, 215 is trending toward a specification or value that is expected or desired.

Determined behavioral characteristics 390A-N may indicate the at least one component 152, 153, 205, 210, 215 is weakened, failing, about to fail, but also determine a state relative to some expected or anticipated value. The determined state can be weakened; not weakened; failing; not failing; within acceptable parameters (e.g., specifications or expected values) under certain operating conditions 391A-B; and outside of acceptable parameters under other operating conditions 391C-D. The determined behavioral characteristics 390A-N do not need to classify the at least one component 152, 153, 205, 210, 215 in a particular state. In some implementations, the behavioral characteristics 390A-N may just deviate from normal values that are expected, but there does not need to be a state determination step.

The applying the one or more PCS diagnostics models 395A-N trained to determine behavioral characteristics 390A-N of the at least one component 152, 153, 205, 210, 215 of the PCS 104 based on the measured input current 122A, the input voltage 123A, the output current 122B, and the output voltage 123B and the one or more behavioral patterns 399A-N previously associated with the abnormally behaving components of the PCS 104 can include the following. First, applying the one or more PCS diagnostics models 395A-N to the measured input current 122A, the input voltage 123A, the output current 122B, and the output voltage 123B and the one or more behavioral patterns 399A-N over a plurality of time periods 398A-N to determine the behavioral characteristics 390A-N. Second, selecting one or more operating conditions 391A-N based on the applied one or more PCS diagnostics models 395A-N responsive to the determined behavioral characteristics 390A-N.

The applying the one or more PCS diagnostics models 395A-N to the measured input current 122A, the input voltage 123A, the output current 122B, and the output voltage 123B and the one or more behavioral patterns 399A-N over the plurality of time periods 398A-N to determine the behavioral characteristics 390A-N can include the following. First, feeding the measured input current 122A, the input voltage 123A, the output current 122B, and the output voltage 123B into the one or more PCS diagnostics models 395A-N. Second, holding the measured input current 122A, the input voltage 123A, the output current 122B, and the output voltage 123B over the plurality of time periods 398A-N. Third, matching the measured input current 122A, the input voltage 123A, the output current 122B, and the output voltage 123B over the plurality of time periods 398A-N against the behavioral patterns 399A-N previously associated with abnormally behaving components of the PCS 104.

Based on the determined behavioral characteristics 390A-N, an operation, such as function, of the PCS 104 and externally connected or related components of the energy storage system 101 can be adjusted automatically or manually. For example, the control system 115 can be configured to adjust a normal operation 392 or a maintenance operation 394 of the PCS 104 responsive to the selected one or more operating conditions 391A-N. The selected one or more operating conditions 391A-N can include applying an operational bias 393, such as changing one or more operating limits, changing one or more operating profiles, reducing power limits, limiting operation to a voltage range, reducing a rate of change of power output, or changing an active/reactive power ratio. The adjustments based on the determined behavioral characteristics 390A-N do not require applying the operational bias 393, such as adjusting operating limits or operating profiles. For example, the adjustment can include replacing or turning off (automatically or manually) the at least one component 152, 153, 205, 210, 215 of the PCS 104; modifying a setting on a connected device like a transformer; changing a setting on a capacitor bank; or taking manual actions by an operator of the energy storage system 101.

Operational bias 393 is not limited to operational changes, but can be an operational adjustment or an operation during a normal operation 392 to dispatch a required power flow 112, such as minor and major changes to the normal operation 392. The operational bias 393 can include running the PCS 104 in a certain way, such as varying a temperature, current carrying capability, etc. The operational bias 393 can be a small deviation to the normal operation 392 during a primary operation of the energy storage system 101. The normal operation 392 can be when the energy storage system 101 is putting energy on and off the electrical application 103.

The maintenance operation 394 can be a wholly separate operational dispatch, such as a discrete function, not for the purpose of dispatching a required power flow 112. The maintenance operation 394 can occur separately for dedicated purposes of extending a lifetime of the at least one component 152, 153, 205, 210, 215 of the PCS 104. The difference between normal operation 392 and the maintenance operation 394 can be whether adjustments to extend the lifetime of the at least one component 152, 153, 205, 210, 215 of the PCS 104 are being performed while performing the primary function of the energy storage system 101 or as a discrete function to extend lifetime of the abnormally behaving components.

The operational bias 393 can be based on the insight that the degree of abnormal behavior of the at least one component 152, 153, 205, 210, 215 of the PCS 104 can be reduced based on selected one or more operating conditions 391A-N as to how the energy storage system 101 is operated. For example, a selected operating condition 391A can be a certain temperature region that can make the at least one component 152, 153, 205, 210, 215 behave within expected specifications or anticipated values. Another selected operating condition 391B can be an electrical resistance that makes up components of the energy storage system 101 and choosing to operate the components with different electrical resistances to improve lifetime of the at least one component 152, 153, 205, 210, 215. These selected one or more operating conditions 391A-B can be applied as an operational bias 393 that is introduced during a normal operation 392 to intentionally bring the PCS 104 into an operational state where anomalous behavior of the at least one component 152, 153, 205, 210, 215 will be reduced, for example, minimized.

The selected one or more operating conditions 391A-N can include a temperature, an electrical resistance, a current rate (C-rate), a current carrying capability, an eddy current, a conductance, a power pulse pattern during charging or discharging, other charging and discharging characteristics, battery storage element characteristics, impedance of AC and DC components, adjusting rates, other electrical characteristics, or issuing different power commands 183A-N.

The at least one component 152, 153, 205, 210, 215 of the PCS 104 can include a power conversion unit 152; a heating, ventilation, and air conditioning (HVAC) equipment 153; a power inverter 205; a rectifier 210; or a DC-DC converter 215. The determined behavioral characteristics 390A-N can indicate the at least one component 152, 153, 205, 210, 215 of the PCS 104 is weakened or failing. For example, a selected operating condition 391A can automatically increase cooling via the HVAC equipment 153 of the PCS 104 to extend a lifetime of the power inverter 205 of the PCS 104.

In an example, the input current 122A and the input voltage 123A can be measured at a high frequency on the input side 190. The output current 122B and the output voltage 123B can be measured at the high frequency on the output side 191. The high frequency can exceed a switching frequency of the PCS 104 and be at least approximately 1 kilohertz (1 kHz). For example, the high frequency can be above the AC sine wave frequency, for example, above approximately 10 kHz, in the tens of thousands of Hz range. Taking measurements of the input current 122A, the input voltage 123A, the output current 122B, and the output voltage 123B at the high frequency sampling can advantageously increase the resolution of the fingerprint of components 152, 153, 205, 210, 215 of the PCS 104. The high frequency sampling of measurements enables the PCS diagnostics models 395A-N to ascertain whether there are weakened or damaged components 152, 153, 205, 210, 215 in the PCS 104. If the frequency of the measurements is too low, the resolution of the fingerprint may be too little and the one or more behavioral patterns 399A-N previously associated with abnormally behaving components of the PCS 104 may not be detectable, such that the anomalous behavior cannot be observed.

Control system 115 of FIG. 3A and array controller 170 of FIG. 3B include a network communication interface 311 configured for wired or wireless communication over the network 305. The control system 115 and the array controller 170 further include a memory 313, and a processor 312 coupled to the network communication interface 311 and the memory 313. As shown, the memory 313 of the control system 115 and the array controller 170 is configured to store PCS diagnostics programming 330A; behavioral characteristics 390A-N; operating conditions 391A-N, PCS diagnostics models 395A-N; time periods 398A-N, and behavioral condition patterns 399A-N. The memory 313 of the control system 115 and the array controller 170 is further configured to store a required power flow 112; battery conditions 116A-O (including a state of charge 116A); power commands 183A-N; a normal operation 392; an operational bias 393, a maintenance operation 394; and system data 380A-N, including battery data 111A-N, environmental condition data 365A-N from the energy storage nodes 105A-N, and PCS data 157A-N (including the environmental condition data 165A-N from the PCSs 104A-N). The control system 115 and the array controller 170 can also include sensors 315A-N coupled to the processor 312 to detect or monitor various system parameters, such as power, temperature, voltage, current, resistance, and/or impedance. For example, the sensors 315A-N, battery sensors 375A-N can be coupled to the power bus 125 and the DC link (DC bus) 225.

Control system 115 and the array controller 170 can be configured to receive or store a required power flow 112 or a power capacity for an electrical application 103 and to dispatch the required power flow 112 across the plurality of energy storage nodes 105A-N. The required power flow 112 can include an active power (e.g., measured in kW or mW), a reactive power (e.g., measured in kVARs), or a total system power discharge or charge requirement. The required power flow 112 can be a power command 183 for the electrical application 103 based on a customer or independent system operator request received over the network 305 from the electrical application 103, in which case the power command 183 is externally determined. The power capacity can be apparent power (e.g., kVA or MVA), such as name plate capacity measured in volt-amperes that can be used for power electronics or electronic equipment to define capabilities in terms of overall power. Both active power and reactive power come together to form apparent power and manufacturers define the capability of the power capacity of power electronics equipment based on the apparent power.

The power command 183 for the electrical application 103 can be based on parameters in a customer or independent system operator request received over the network 305 from the electrical application 103. For example, the parameters can be to provide frequency regulation with a deadband and a slope of the response. The control system 115 can take the parameters and attempt to determine the power command 183, for example, based on satisfying the customer or independent system operator request for the electrical application 103.

Control system 115 can take the required power flow 112 needed for the electrical application 103, for example, as requested by a customer or software application and determine the optimal way to distribute the required power flow 112 across all of the energy storage nodes 105A-N. This optimization may be conducted in several manners, for example using traditional operational optimization techniques or machine-learning based techniques. The control system 115 can include one or more processors, controllers, or computing devices that can be configured to perform closed loop management of real and reactive power supplied to the electrical application 103.

Energy storage nodes 105A-N include a control subsystem 110 in FIG. 3A and a node controller 172 in FIG. 3B, battery storage elements 106A-N, and a power conversion subsystem 107 (or a power conversion system 104), which can reside on each individual energy storage node 105A-N. The control subsystem 110 and the node controller 172 of the energy storage nodes 105A-N include a network communication interface 351 configured for wired or wireless communication over the network 305. The control subsystem 110 and the node controller 172 further include a memory 353, and a processor 352 coupled to the network communication interface 351 and the memory 353. As shown, the memory 353 of the control subsystem 110 and the node controller 172 is configured to store PCS diagnostics programming 330B, battery data 111A-N, battery conditions 116A-O (including a state of charge 116A), and environmental condition data 165A-N, 365A-N.

The control subsystem 110 and the node controller 172 further include environmental sensors 370A-N and battery sensors 375A-N coupled to the processor 352. Environmental sensors 370A-N can collect environmental condition data 365A-N, for example, by measuring humidity and temperature inside of an enclosure 500 of the energy storage nodes 105A-N, such as one or more battery cubes 230A-N. Battery sensors 375A-N can include a voltage sensor 375A, a current sensor 375B, and a temperature sensor 375C to measure readings of battery data 111A-N, such as a voltage 111A, a current 111B, a temperature 111C, or other physical phenomena occurring within the battery storage elements 106A-N. The memory 353 can store the environmental condition data 365A-N collected by the environmental sensors 370A-N and the battery data 111A-N measured by the battery sensors 375A-N.

The control subsystem 110 or the control system 115 can be configured to determine at least one battery condition 116A-O, 316A-N about one or more of the energy storage nodes 105A-N from the battery data 111A-N. The battery conditions 116A-O, 316A-N can be algorithmically determined estimates from battery data 111A-N, readings from the sensors 315A-N, battery sensors 375A-N that monitor various system parameters on the power bus 125, DC link (DC bus) 225, or a combination thereof, for example. State estimating algorithms can take the measured readings of battery data 111A-N, including the voltage 111A, the current 111B, the temperature 111C, or a combination thereof as input parameters and estimate the battery conditions 116A-O, 316A-N based on the battery data 111A-N.

For example, a state of charge 116A, 316A-N is a state estimate derived from the voltage 111A and the current 111B readings. The state of charge 116A, 316A-N can be derived from the control system 115. Alternatively or additionally, at least one battery management system (BMS) or the node controller 172 can derive the state of charge 116A, 316A-N. The state of charge 116A, 316A-N can be determined at a variety of levels. In a first example, the state of charge 116A, 316A-N can be determined at the battery storage element level 106, such as for individual battery storage elements 106A-N (e.g., battery racks, battery modules, and battery cells). In a second example, the state of charge 116A, 316A-N can be determined at the battery cube level, such as for individual battery cubes 230A-N. In a third example, the state of charge 116A, 316A-N can be determined at the energy storage node level, such as for a first energy storage node 105A that includes a plurality of battery cubes 230A-N.

The control subsystem 110 can include at least one battery management system (BMS) to determine the state of charge 116A, 316A-N. The SOC 116A, 316A-N provided by a battery management system, for example, can be based on Coulombe counting and be a number from 0-100% as to whether a battery storage element 106A-N, such as a battery cell, is full or empty. The SOC 116A, 316A-N can be provided at the battery cell level for all of the battery cubes 230A-N on that DC bus 225. Each battery rack of a battery cube 230 can have a BMS and that information can be propagated for each individual battery cell to a system level BMS to determine the SOC 116A, 316A-N of each battery storage element 106A-N, such as each individual battery rack, battery module, or battery cell in the battery cube 230 of the energy storage node 105A.

SOC calculations may look at voltage on the DC bus 225 over time. In some examples, the SOC 116A, 316A-N can be determined for an entire energy storage node 105A-N (e.g., a first energy storage node 105A including all seven battery cubes 230A-G of all battery storage elements 106A-N behind the first energy storage node 105A). For example, the SOC 116A, 316A-N can be a calculated number of all battery cubes 230A-G put together on that first energy storage node 105A based on how much current is being put through and how much energy can get out. The SOC 116A, 316A-N can be one parameter reading for an entire DC bus 225 for the first energy storage node 105A.

Some state estimating algorithms may receive measured readings from the battery sensors 375A-N of the control subsystem 110 and sensors 315A-N of the control system 115 to derive other parameters, such as real time power. For example, real time power may be derived as a parameter in order to determine the battery conditions 116A-O.

The control system 115 and the array controller 170 can manage power commands 183A-N to the control subsystem 110 and the node controller 172 respectively, to charge or discharge the plurality of energy storage nodes 105A-N based on the required power flow 112. For example, the control system 115 and the array controller 170 can send the power commands 183A-N based on the total required power flow 112 to the plurality of energy storage nodes 105A-N. Alternatively or additionally, the control subsystem 110 and the node controller 172 can issue the power commands 183A-N directly at the plurality of energy storage nodes 105A-N based on the required power flow 112.

FIG. 3C is a block diagram of the control system 115 depicting various types of battery conditions 116A-O. The battery conditions 116A-O can include: a state of charge 116A, a temperature 116B, a power capability 116C, remaining energy capacity 116D, an internal resistance or impedance 116E, a degradation of a cathode active material 116F, a degradation of an anode active material 116G, a degree of growth of a solid-electrode interphase (SEI) layer 116H, remaining lithium inventory/lithium inventory loss 116I, lithium plating on an anode or a cathode active material 116J, a lithium dendrite growth on an anode active material 116K, depositing of electrode decomposition products on an anode or a cathode active material 116L, a current distribution non-uniformity in an anode or a cathode active material 116M, a phase of a cathode active material 116N, a phase of an anode active material 1160, or a combination thereof.

The battery conditions 116A-O can be determined by applying power pulse patterns during charging or can discharging cycles that include a higher frequency charge or discharge swing. In an example, the power pulse pattern during battery charging can include to charge to a first voltage for a first period of time, stop charging for a second period of time, then charge to a second voltage for a third period of time, stop charging for a fourth period of time, and then charge to a third voltage for a fifth period of time. The power pulse pattern during battery discharging can include to discharge to a first voltage for a first period of time, stop discharging for a second period of time, then discharge to a second voltage for a third period of time, stop discharging for a fourth period of time, and then discharge to a third voltage for a fifth period of time. The voltages and timing (e.g., periods of time) of the power pulse patterns 118B-C can be adjusted during the charging and discharging cycles to provide a set of battery data 111A-N to feed the state estimating algorithms in order to determine the battery conditions 116A-O.

FIG. 4A is a PCS diagnostics protocol 400 for the energy storage system 101 of FIG. 1A that is implemented by the control system 115, the control subsystem 110, and the plurality of energy storage nodes 105A-N. In the example of FIG. 4A, the PCS diagnostics protocol 400 can be implemented in the PCS diagnostics programming 330A of the control system 115, the PCS diagnostics programming 330B of the control subsystem 110, or both. Alternatively or additionally, PCS diagnostics programming 330C can reside on the PCS 104.

FIG. 4B is the PCS diagnostics protocol 400 for the energy storage system 101 of FIGS. 1B-C that is implemented by the various controllers 170-173 of the control system 115, and the plurality of energy storage nodes 105A-N. In the example of FIG. 4B, the PCS diagnostics protocol 400 can be implemented in the PCS diagnostics programming 330A of the array controller 170, the PCS diagnostics programming 330B of the node controller 172, or both.

Referring to both FIGS. 4A-B, execution of PCS diagnostics programming 330A stored in a memory 313 by a processor 312 of the control system 115 (e.g., array controller 170) configures the control system 115 (e.g., array controller 170) to implement blocks 405 and 410 described below. Execution of PCS diagnostics programming 330B stored in a memory 353 by a processor 352 of the control subsystem 110 (e.g., node controller 172) can configure the control subsystem 110 (e.g., node controller 172) to implement some portion or all of blocks 405 and 410 described below. More generally, the execution of the PCS diagnostics programming 330A-B by one or more processors 312, 352 can configure one or more controllers 110, 115, 170-173 to implement blocks 405 and 410 below.

Beginning in block 405, the PCS diagnostics protocol 400 includes to measure a power conversion system (PCS) data 157A-N including an input current 122A and an input voltage 123A on an input side 190 of a PCS 104 and an output current 122B and an output voltage 123B on an output side 191 of the PCS 104.

Moving now to block 410, the PCS diagnostics protocol 400 further includes to apply one or more PCS diagnostics models 395A-N trained to determine behavioral characteristics 390A-N of at least one component 152, 153, 205, 210, 215 of the PCS 104 based on the measured input current 122A, the input voltage 123A, the output current 122B, and the output voltage 123B and one or more behavioral patterns 399A-N previously associated with abnormally behaving components of the PCS 104.

PCS diagnostics models 395A-N can be trained to identify the at least one component 152, 153, 205, 210, 215 that is behaving in an anomalous or unexpected fashion. Training data for the PCS diagnostics models 395A-N can be representative of behavioral patterns 399A-N of a PCS 104, such as the power inverter 205. The training data may be supplemented or entirely constituted from the system data 380A-N, including PCS data 157A-N, or from an installation of the same or a similar type of energy storage system 101. The training data can initially be based on historical or live PCS data 157A-N from the PCS 104 of the energy storage system 101 or another installation of the same or similar type of energy storage system 101. The control system 115 may continually update the training data to improve accuracy of the PCS diagnostics models 395A-N to identify abnormally behaving components of the PCS 104.

PCS diagnostics models 395A-N can identify a relative state of the at least one component 152, 153, 205, 210, 215 or whether the at least one component 152, 153, 205, 210, 215 is within an expected value, outside of the expected value, measure a trend away from the expected value, or toward the expected value.

PCS diagnostics models 395A-N may be a machine learning or an artificial intelligence model, and may be a model which utilizes regression analysis and Markov chains to make associations between seemingly disparate raw data points in order to better understand cause-and-effect relationships. Such PCS diagnostics models 395A-N may constitute or utilize a convolutional neural net, where the physical mechanism between the input and output is not fully understood. For example, PCS diagnostics models 395A-N may ascertain, or may be programmed to know, that behavioral characteristics 390A-N change with temperature 165A, 365A. And that the change in behavioral characteristics 390A-N may not be linear with respect to time; temperature 165A, 365A; or state of charge 116, 316A-N; or rate of state of charge change.

PCS diagnostics models 395A-N can be fed multivariate inputs from the PCS diagnostics programming 330A-B. The PCS diagnostics models 395A-N can decide the selected one or more operating conditions 391A that will have the greatest impact on extending the lifetime of the at least one component 152, 153, 205, 210, 215 of the PCS 104. For example, running at a certain power profile or higher operating temperature can change the electrical resistance, current carrying capability, or other charging and discharging characteristics.

PCS diagnostics models 395A-N can take inputs, such as various system data 380A-N, including PCS data 157A-N and states of charge, 116A, 316A-N and be designed to identify abnormally behaving components 152, 153, 205, 210, 215 through a set of known or learned heuristics. The PCS diagnostics models 395A-N may not have any training data input from the PCS 104 but can have heuristics based on being trained on other commonly operated energy storage systems. The PCS diagnostics models 395A-N can select the one or more operating conditions 391A-N including a lower C-rate, a higher C-rate, spending more time towards a top of charge, spending more time towards a bottom of charge, using a narrower depth of discharge, using a broader depth of discharge, pause, pulse, pulse positively, pulse negatively, pulse only positively, pulse only negatively, etc.

In FIG. 4B, the core controllers 171A-N, node controllers 172A-N, and enclosure controllers 173A-N can implement a subset or all of the blocks 405 and 410 of the PCS diagnostics protocol 400 without the central array controller 170. In some examples, the functionality of the array controller 170 and the PCS diagnostics programming 330A-B can be separated into one or more controllers or computing devices. The PCS diagnostics programming 330A-B may be stored and executed on the one or more controllers or computing devices.

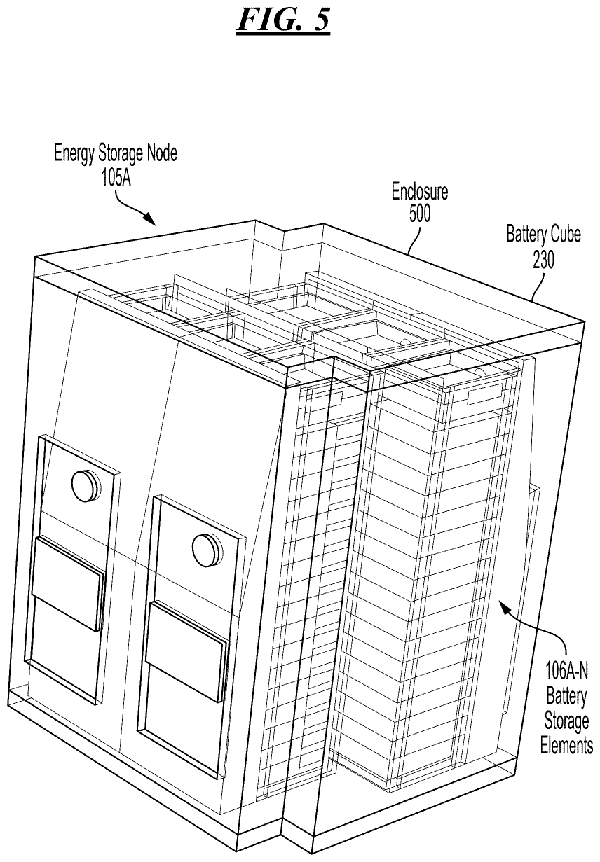

FIG. 5 is a cutaway view of the first energy storage node 105A of the plurality of energy storage nodes 105A-N and shows details of a plurality of battery storage elements 106A-N. As shown, the energy storage node 105A includes an enclosure 500, such as a physical housing to store a plurality of battery storage elements 106A-N. The battery storage elements 106A-N can be a collection of one or more batteries, such as a plurality of battery strings or battery banks, which are organized logically, physically, and electrically.

In the example of FIG. 5, the battery storage elements 106A-N can include battery racks (e.g., six are shown) that hold a respective stack of battery modules (e.g., seventeen are shown). The battery modules can include an array of prismatic, pouch, or cylindrical battery cells that are packaged together to increase voltage, amperage, or both. In some examples, battery modules may include an electric vehicle battery pack, e.g., a collection of lithium-ion battery cells that are packaged together.

Each of the energy storage nodes 105A-N can include a collection of one or more enclosures 500A-N like that shown in FIG. 5 that house a plurality of battery storage elements 106A-N packaged together as a battery cube 230 in the example. Of course, the enclosure 500 can be shaped in a variety of other form factors. Each of the battery cubes 230A-N can further include a respective enclosure controller 173A-N that is controlled by a respective node controller 172A-N as part of the control system 115.

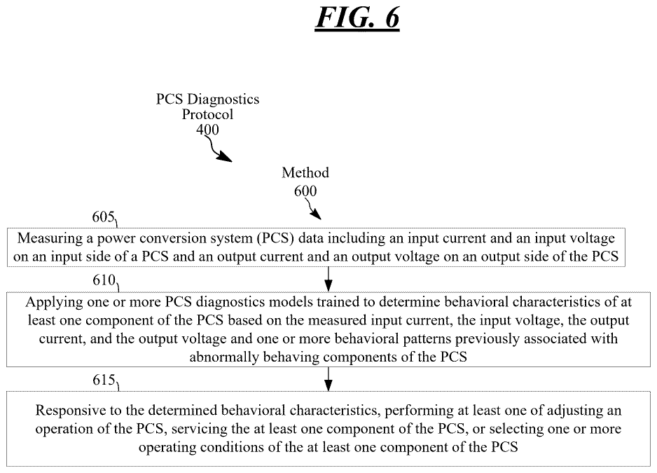

FIG. 6 is a flowchart of a method 600 that can be implemented for PCS diagnostics of the energy storage system 101. In the example of FIG. 6, the method 600 implements the PCS diagnostics protocol 400 of FIG. 4. Beginning in step 605, the method 600 includes measuring a power conversion system (PCS) data 157A-N including an input current 122A and an input voltage 123A on an input side 190 of a PCS 104 and an output current 122B and an output voltage 123B on an output side 191 of the PCS 104. The determined behavioral characteristics 390A-N can indicate the at least one component 152, 153, 205, 210, 215 of the PCS 104 is weakened or failing.

Continuing to step 610, the method 600 further includes applying one or more PCS diagnostics models 395A-N trained to determine behavioral characteristics 390A-N of at least one component 152, 153, 205, 210, 215 of the PCS 104 based on the measured input current 122A, the input voltage 123A, the output current 122B, and the output voltage 123B and one or more behavioral patterns 399A-N previously associated with abnormally behaving components of the PCS 104.

The applying the one or more PCS diagnostics models 395A-N trained to determine behavioral characteristics 390A-N of the at least one component 152, 153, 205, 210, 215 of the PCS 104 based on the measured input current 122A, the input voltage 123A, the output current 122B, and the output voltage 123B and the one or more behavioral patterns 399A-N previously associated with the abnormally behaving components of the PCS 104 can include the following. First, applying the one or more PCS diagnostics models 395A-N to the measured input current 122A, the input voltage 123A, the output current 122B, and the output voltage 123B and the one or more behavioral patterns 399A-N over a plurality of time periods 398A-N to determine the behavioral characteristics 390A-N. Second, selecting one or more operating conditions 391A-N based on the applied one or more PCS diagnostics models 395A-N responsive to the determined behavioral characteristics 390A-N.

The applying the one or more PCS diagnostics models 395A-N to the measured input current 122A, the input voltage 123A, the output current 122B, and the output voltage 123B and the one or more behavioral patterns 399A-N over the plurality of time periods 398A-N to determine the behavioral characteristics 390A-N can include the following. First, feeding the measured input current 122A, the input voltage 123A, the output current 122B, and the output voltage 123B into the one or more PCS diagnostics models 395A-N. Second, holding the measured input current 122A, the input voltage 123A, the output current 122B, and the output voltage 123B over the plurality of time periods 398A-N. Third, matching the measured input current 122A, the input voltage 123A, the output current 122B, and the output voltage 123B over the plurality of time periods 398A-N against the behavioral patterns 399A-N previously associated with abnormally behaving components of the PCS 104.

Finishing now in block 615, the method 600 further includes responsive to the determined behavioral characteristics 390A-N, performing at least one of adjusting an operation of the PCS 104, servicing the at least one component 152, 153, 205, 210, 215 of the PCS 104, or selecting an operating condition 391A-N of the at least one component 152, 153, 205, 210, 215 of the PCS 104.

In block 615, adjustments to the operation of the PCS 104 can include taking actions or modifications based on the determined behavioral characteristics 390A-N. Based on the behavioral characteristics 390A-N and identification of abnormally behaving components, an action can be taken to mitigate the determined behavioral characteristics 390A-N. There can be two types of actions taken to address the abnormal or anomalous behavioral characteristics 390A-N of the at the at least one component 152, 153, 205, 210, 215. First, manual action can be taken by servicing equipment, for example, turning off or replacing equipment, such as the at least one component 152, 153, 205, 210, 215; or adjusting a setting on a tap changer or transformer (this action may also be automated outside of the PCS 104 by automatically changing a tap changer, a capacitor bank, or a fan speed). Second, automated action can be taken by having the control system 115 adjust an operating condition 391A, such as changing to a lower power limit or a voltage range that the PCS operates 104 within based on a rule or heuristic that is automated. Adjusting the operating condition 391A, such as an operating environment, for example, with a tap changer can affect electrical characteristics upstream of the PCS 104 to mitigate some of the determined behavioral characteristics 390A-N.

For example, the selected one or more operating conditions 391A-N can be a different temperature, changing electrical resistance, current carrying capability, range of state of charge 116A, C-rate, or other charging and discharging characteristics. The temperature can be a cell temperature, ambient temperature, internal air temperature, a coolant temperature, etc.

Operating conditions 391A-N can be observations of the PCS 104 or about different components, such as the battery storage elements 106A-N, bus bars, battery modules, or power cabling of the energy storage system 101 that can be targeted based on characteristics and a desired outcome. This results in differential performance as the energy storage system 101 operates.

As another example, it may be identified that running the energy storage system 101 in the selected one or more operating conditions 391A-N, such as a certain type or pattern of operation, extends a lifetime of at least one component 152, 153, 205, 210, 215. The PCS 104, various energy storage nodes 105A-N, or battery cores 151A-N in the energy storage system 101 can have an operational bias 393 to run in certain states of operation more frequently to extend the lifetime of the at least one component 152, 153, 205, 210, 215.

PCS diagnostics protocol 400 can extend a lifetime of a first PCS 104A in a group of PCSs 104A-C without regard for the other PCSs 104B-C in the group. The PCS diagnostics protocol 400 may select PCSs 104B-C to perform at operating limits which do not extend lifetime. In doing so, the other PCSs 114B-C may reach the end of lifetime earlier than the first PCS 104A, resulting in a staggered maintenance schedule. A staggered maintenance schedule may be desirable to prevent a catastrophic failure or reduce risk of a catastrophic failure of all or a large number of PCSs 104A-C nearly-simultaneously. By having the group of PCSs 104A-C reach the end of lifetime on a staggered schedule, the energy storage system 101 may operate more robustly and more effectively meet demand. However, it may also be optimal to extend the lifetime of all PCSs 114A-C in the group such that the end of lifetime is reached at approximately the same time, in order to reduce parts, labor, and mobilization costs across the group of PCSs 104A-C.

In the examples above, the energy system 102, energy application 103, power conversion system 104, energy storage nodes 105A-N, control subsystem 110, control system 115, array controller 170, core controllers 171A-N, node controllers 172A-N, enclosure controllers 173A-N, etc. each include a network communication interface 161, 311, 351 for wired or wireless communication over one or more networks 305A-N. The networks 305A-N interconnect the links to/from the network communication interfaces 161, 311, 351 of the devices, so as to provide data communications amongst the energy application 103, energy storage nodes 105A-N, control system 115, array controller 170, core controllers 171A-N, node controllers 172A-N, enclosure controllers 173A-N, etc. Networks 305A-N may support data communication by equipment at the premises via wired (e.g., cable or fiber) media or via wireless (e.g., Wi-Fi, Bluetooth™, ZigBee, LiFi, IrDA, etc.) or combinations of wired and wireless technology.

Any of the functionality of the PCS diagnostics protocol 400, including PCS diagnostics programming 330A-B, described herein for the energy system 102, electrical application 103, power conversion system 104, energy storage nodes 105A-N, control subsystem 110, control system 115, array controller 170, core controllers 171A-N, node controllers 172A-N, enclosure controllers 173A-N, etc. can be embodied in one or more applications or firmware as described previously. According to some embodiments, “function,” “functions,” “application,” “applications,” “instruction,” “instructions,” or “programming” are program(s) that execute functions defined in the programs. Various programming languages can be employed to create one or more of the applications, structured in a variety of manners, such as object-oriented programming languages (e.g., Objective-C, Java, or C++) or procedural programming languages (e.g., C or assembly language).

In the examples above, the energy system 102, energy application 103, power conversion system 104, energy storage nodes 105A-N, control subsystem 110, control system 115, array controller 170, core controllers 171A-N, node controllers 172A-N, enclosure controllers 173A-N, etc. can each include a processor. As used herein, a processor 162, 312, 352 is a hardware circuit having elements structured and arranged to perform one or more processing functions, typically various data processing functions. Although discrete logic components could be used, the examples utilize components forming a programmable central processing unit (CPU). A processor 162, 312, 352 for example includes or is part of one or more integrated circuit (IC) chips incorporating the electronic elements to perform the functions of the CPU. The processors 162, 312, 352 for example, may be based on any known or available microprocessor architecture, such as a Reduced Instruction Set Computing (RISC) using an ARM architecture. Of course, other processor circuitry may be used to form the CPU or processor hardware in. The illustrated examples of the processors 162, 312, 352 can include one microprocessor or a multi-processor architecture. A digital signal processor (DSP) or field-programmable gate array (FPGA) could be suitable replacements for the processors 162, 312, 352, but may consume more power with added complexity.

The applicable processor 162, 312, 352 executes programming or instructions to configure the energy system 102, energy application 103, power conversion system 104, energy storage nodes 105A-N, control subsystem 110, control system 115, array controller 170, core controllers 171A-N, node controllers 172A-N, enclosure controllers 173A-N, etc. to perform various operations. For example, such operations may include various general operations (e.g., a clock function, recording and logging operational status and/or failure information) as well as various system-specific operations (e.g., energy management) functions. Although a processor 162, 312, 352 may be configured by use of hardwired logic, typical processors are general processing circuits configured by execution of programming, e.g., instructions and any associated setting data from the memories 163, 313, 353 shown or from other included storage media and/or received from remote storage media.

In the examples above, the energy system 102, energy application 103, power conversion system 104, energy storage nodes 105A-N, control subsystem 110, control system 115, array controller 170, core controllers 171A-N, node controllers 172A-N, enclosure controllers 173A-N, etc. each include a memory. The memory 163, 313, 353 may include a flash memory (non-volatile or persistent storage), a read-only memory (ROM), and a random access memory (RAM) (volatile storage). The RAM serves as short term storage for instructions and data being handled by the processors 162, 312, 352 e.g., as a working data processing memory. The flash memory typically provides longer term storage.

Of course, other storage devices or configurations may be added to or substituted for those in the example. Such other storage devices may be implemented using any type of storage medium having computer or processor readable instructions or programming stored therein and may include, for example, any or all of the tangible memory of the computers, processors or the like, or associated modules.

Hence, a machine-readable medium or a computer-readable medium may take many forms of tangible storage medium. Non-volatile storage media include, for example, optical or magnetic disks, such as any of the storage devices in any computer(s) or the like, such as may be used to implement the client device, media gateway, transcoder, etc. shown in the drawings. Volatile storage media include dynamic memory, such as main memory of such a computer platform. Tangible transmission media include coaxial cables; copper wire and fiber optics, including the wires that comprise a bus within a computer system. Carrier-wave transmission media may take the form of electric or electromagnetic signals, or acoustic or light waves such as those generated during radio frequency (RF) and infrared (IR) data communications. Common forms of computer-readable media therefore include for example: a floppy disk, a flexible disk, hard disk, magnetic tape, any other magnetic medium, a CD-ROM, DVD or DVD-ROM, any other optical medium, punch cards, paper tape, any other physical storage medium with patterns of holes, a RAM, a PROM and EPROM, a FLASH-EPROM, any other memory chip or cartridge, a carrier wave transporting data or instructions, cables or links transporting such a carrier wave, or any other medium from which a computer may read programming code and/or data. Many of these forms of computer readable media may be involved in carrying one or more sequences of one or more instructions to a processor for execution.

According to exemplary embodiments of the present disclosure the one or more processors and control circuits can include one or more of any known general purpose processor or integrated circuit such as a central processing unit (CPU), microprocessor, field programmable gate array (FPGA), Application Specific Integrated Circuit (ASIC), Digital Signal Processor (DSP), or other suitable programmable processing or computing device or circuit as desired that is specially programmed to perform operations for achieving the results of the exemplar embodiments described herein. The processor(s) can be configured to include and perform features of the exemplary embodiments of the present disclosure, such as the PCS diagnostics protocol 400 and the PCS diagnostics programming 330A-B. The features can be performed through program code encoded or recorded on the processor(s), or stored in a non-volatile memory device, such as Read-Only Memory (ROM), erasable programmable read-only memory (EPROM), or other suitable memory device or circuit as desired. Accordingly, such computer programs can represent controllers of the computing device.

In another exemplary embodiment, the program code, such as the PCS diagnostics protocol 400 and the PCS diagnostics programming 330A-B, can be provided in a computer program product having a non-transitory computer readable medium, such as Magnetic Storage Media (e.g. hard disks, floppy discs, or magnetic tape), optical media (e.g., any type of compact disc (CD), or any type of digital video disc (DVD), or other compatible non-volatile memory device as desired) and downloaded to the processor(s) for execution as desired, when the non-transitory computer readable medium is placed in communicable contact with the processor(s).

The one or more processors 162, 312, 352 can be included in a computing system that is configured with components such as memory, a hard drive, an input/output (I/O) interface, a communication interface, a display and any other suitable component as desired. The exemplary computing device can also include a communications interface. The communications interface can be configured to allow software and data to be transferred between the computing device and external devices. Exemplary communications interfaces can include a modem, a network interface (e.g., an Ethernet card), a communications port, a PCMCIA slot and card, or any other suitable network communication interface as desired. Software and data transferred via the communications interface can be in the form of signals, which can be electronic, electromagnetic, optical, or other signals as will be apparent to persons having skill in the relevant art. The signals can travel via a communications path, which can be configured to carry the signals and can be implemented using wire, cable, fiber optics, a phone line, a cellular phone link, a radio frequency link, or any other suitable communication link as desired.

Where the present disclosure is implemented using programming or software, including the PCS diagnostics protocol 400 and the PCS diagnostics programming 330A-B, the programming or software can be stored in a computer program product or non-transitory computer readable medium and loaded into the computing device using a removable storage drive or communications interface. In an exemplary embodiment, any computing device, such as control subsystem 110, control system 115 and controllers 170-173, disclosed herein can also include a display interface that outputs display signals to a display unit, e.g., LCD screen, plasma screen, LED screen, DLP screen, CRT screen, or any other suitable graphical interface as desired.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual such relationship or order between such entities or actions. The terms “comprises,” “comprising,” “includes,” “including,” “has,” “having,” “containing,” “contain”, “contains,” “with,” “formed of,” or any other variation thereof, are intended to cover a non-exclusive inclusion, such that a process, method, article, or apparatus that comprises or includes a list of elements or steps does not include only those elements or steps but may include other elements or steps not expressly listed or inherent to such process, method, article, or apparatus. An element preceded by “a” or “an” does not, without further constraints, preclude the existence of additional identical elements in the process, method, article, or apparatus that comprises the element. Unless otherwise stated, the articles “a” or “an” preceding an element mean one or more of the elements.

Unless otherwise stated, any and all measurements, values, ratings, positions, magnitudes, sizes, angles, and other specifications that are set forth in this specification, including in the claims that follow, are approximate, not exact. Such amounts are intended to have a reasonable range that is consistent with the functions to which they relate and with what is customary in the art to which they pertain. For example, unless expressly stated otherwise, a parameter value or the like may vary by as much as ±5% or as much as ±10% from the stated amount. The terms “approximately” and “substantially” mean that the parameter value or the like varies up to ±10% from the stated amount.

In addition, in the foregoing Detailed Description, it can be seen that various features are grouped together in various examples for the purpose of streamlining the disclosure. This method of disclosure is not to be interpreted as reflecting an intention that the claimed examples require more features than are expressly recited in each claim. Rather, as the following claims reflect, the subject matter to be protected lies in less than all features of any single disclosed example. Thus, the following claims are hereby incorporated into the Detailed Description, with each claim standing on its own as a separately claimed subject matter.

While the foregoing has described what are considered to be the best mode and/or other examples, it is understood that various modifications may be made therein and that the subject matter disclosed herein may be implemented in various forms and examples, and that they may be applied in numerous applications, only some of which have been described herein. It is intended by the following claims to claim any and all modifications and variations that fall within the true scope of the present concepts.

The scope of protection is limited solely by the claims that now follow. That scope is intended and should be interpreted to be as broad as is consistent with the ordinary meaning of the language that is used in the claims when interpreted in light of this specification and the prosecution history that follows and to encompass all structural and functional equivalents. Notwithstanding, none of the claims are intended to embrace subject matter that fails to satisfy the requirement of Sections 101, 102, or 103 of the Patent Act, nor should they be interpreted in such a way. Any unintended embracement of such subject matter is hereby disclaimed.

What is claimed is:

1. An energy storage system, comprising:
a plurality of energy storage nodes, wherein each of the plurality of energy storage nodes include a plurality of battery storage elements;
a power conversion system (PCS) including a plurality of components;
a control system coupled to the plurality of energy storage nodes and the PCS; and
a plurality of sensors coupled to the control system to detect or monitor various system data, wherein the system data includes PCS data from the PCS;
wherein the control system is configured to:
measure the PCS data including an input current and an input voltage on an input side of the PCS and an output current and an output voltage on an output side of the PCS; and
apply one or more PCS diagnostics models trained to determine behavioral characteristics of at least one component of the PCS based on the measured input current, the input voltage, the output current, and the output voltage and one or more behavioral patterns previously associated with abnormally behaving components of the PCS.

2. The energy storage system of claim 1, wherein the applying the one or more PCS diagnostics models trained to determine behavioral characteristics of the at least one component of the PCS based on the measured input current, the input voltage, the output current, and the output voltage and the one or more behavioral patterns previously associated with the abnormally behaving components of the PCS includes:
applying the one or more PCS diagnostics models to the measured input current, the input voltage, the output current, and the output voltage and the one or more behavioral patterns over a plurality of time periods to determine the behavioral characteristics; and
selecting one or more operating conditions based on the applied one or more PCS diagnostics models responsive to the determined behavioral characteristics.

3. The energy storage system of claim 2, wherein the applying the one or more PCS diagnostics models to the measured input current, the input voltage, the output current, and the output voltage and the one or more behavioral patterns over the plurality of time periods to determine the behavioral characteristics includes:
feeding the measured input current, the input voltage, the output current, and the output voltage into the one or more PCS diagnostics models;
holding the measured input current, the input voltage, the output current, and the output voltage over the plurality of time periods; and
matching the measured input current, the input voltage, the output current, and the output voltage over the plurality of time periods against the behavioral patterns previously associated with abnormally behaving components of the PCS.

4. The energy storage system of claim 2, wherein the control system is configured to adjust a normal operation or a maintenance operation of the PCS responsive to the selected one or more operating conditions.

5. The energy storage system of claim 2, wherein the selected one or more operating conditions include applying an operational bias, changing one or more operating limits, changing one or more operating profiles, reducing power limits, limiting operation to a voltage range, reducing a rate of change of power output, or changing an active/reactive power ratio.

6. The energy storage system of claim 1, wherein the at least one component of the PCS includes a power conversion unit; a heating, ventilation, and air conditioning (HVAC) equipment; a power inverter; a rectifier; or a DC-DC converter.

7. The energy storage system of claim 1, wherein the determined behavioral characteristics indicate the at least one component of the PCS is weakened or failing.

8. The energy storage system of claim 1, wherein:
the input current and the input voltage are measured at a high frequency on the input side;
the output current and the output voltage are measured at the high frequency on the output side; and
the high frequency exceeds a switching frequency of the PCS and is at least approximately 1 kilohertz (1 kHz).

9. A non-transitory computer-readable medium, comprising PCS diagnostics programming, wherein execution of the PCS diagnostics programming by one or more processors configures one or more controllers to:
measure a power conversion system (PCS) data including an input current and an input voltage on an input side of a PCS and an output current and an output voltage on an output side of the PCS; and
apply one or more PCS diagnostics models trained to determine behavioral characteristics of at least one component of the PCS based on the measured input current, the input voltage, the output current, and the output voltage and one or more behavioral patterns previously associated with abnormally behaving components of the PCS.

10. The non-transitory computer-readable medium of claim 9, wherein the applying the one or more PCS diagnostics models trained to determine behavioral characteristics of the at least one component of the PCS based on the measured input current, the input voltage, the output current, and the output voltage and the one or more behavioral patterns previously associated with the abnormally behaving components of the PCS includes:
applying the one or more PCS diagnostics models to the measured input current, the input voltage, the output current, and the output voltage and the one or more behavioral patterns over a plurality of time periods to determine the behavioral characteristics; and
selecting one or more operating conditions based on the applied one or more PCS diagnostics models responsive to the determined behavioral characteristics.

11. The non-transitory computer-readable medium of claim 10, wherein the applying the one or more PCS diagnostics models to the measured input current, the input voltage, the output current, and the output voltage and the one or more behavioral patterns over the plurality of time periods to determine the behavioral characteristics includes:
feeding the measured input current, the input voltage, the output current, and the output voltage into the one or more PCS diagnostics models;
holding the measured input current, the input voltage, the output current, and the output voltage over the plurality of time periods; and
matching the measured input current, the input voltage, the output current, and the output voltage over the plurality of time periods against the behavioral patterns previously associated with abnormally behaving components of the PCS.

12. The non-transitory computer-readable medium of claim 10, wherein the control system is configured to adjust a normal operation or a maintenance operation of the PCS responsive to the selected one or more operating conditions.

13. The non-transitory computer-readable medium of claim 10, wherein the selected one or more operating conditions include applying an operational bias, changing one or more operating limits, changing one or more operating profiles, reducing power limits, limiting operation to a voltage range, reducing a rate of change of power output, or changing an active/reactive power ratio.

14. The non-transitory computer-readable medium of claim 9, wherein the at least one component of the PCS includes a power conversion unit; a heating, ventilation, and air conditioning (HVAC) equipment; a power inverter; a rectifier; or a DC-DC converter.

15. The non-transitory computer-readable medium of claim 9, wherein the determined behavioral characteristics indicate the at least one component of the PCS is weakened or failing.

16. The non-transitory computer-readable medium of claim 9, wherein:
the input current and the input voltage are measured at a high frequency on the input side;
the output current and the output voltage are measured at the high frequency on the output side; and
the high frequency exceeds a switching frequency of the PCS and is at least approximately 1 kilohertz (1 kHz).

17. A method, comprising:
measuring a power conversion system (PCS) data including an input current and an input voltage on an input side of a PCS and an output current and an output voltage on an output side of the PCS;
applying one or more PCS diagnostics models trained to determine behavioral characteristics of at least one component of the PCS based on the measured input current, the input voltage, the output current, and the output voltage and one or more behavioral patterns previously associated with abnormally behaving components of the PCS; and
responsive to the determined behavioral characteristics, performing at least one of adjusting an operation of the PCS, servicing the at least one component of the PCS, or selecting one or more operating conditions of the at least one component of the PCS.

18. The method of claim 17, wherein the applying the one or more PCS diagnostics models trained to determine behavioral characteristics of the at least one component of the PCS based on the measured input current, the input voltage, the output current, and the output voltage and the one or more behavioral patterns previously associated with the abnormally behaving components of the PCS includes:
applying the one or more PCS diagnostics models to the measured input current, the input voltage, the output current, and the output voltage and the one or more behavioral patterns over a plurality of time periods to determine the behavioral characteristics; and
selecting one or more operating conditions based on the applied one or more PCS diagnostics models responsive to the determined behavioral characteristics.

19. The method of claim 18, wherein the applying the one or more PCS diagnostics models to the measured input current, the input voltage, the output current, and the output voltage and the one or more behavioral patterns over the plurality of time periods to determine the behavioral characteristics includes:
feeding the measured input current, the input voltage, the output current, and the output voltage into the one or more PCS diagnostics models;
holding the measured input current, the input voltage, the output current, and the output voltage over the plurality of time periods; and
matching the measured input current, the input voltage, the output current, and the output voltage over the plurality of time periods against the behavioral patterns previously associated with abnormally behaving components of the PCS.

20. The method of claim 17, wherein the determined behavioral characteristics indicate the at least one component of the PCS is weakened or failing.
